(19) United States
(12) Patent Application Publication
(10) Pub. No.: US 2024/0030004 A1
(43) Pub. Date: Jan. 25, 2024

(54) ION BEAM IRRADIATION APPARATUS AND METHOD

(71) Applicant: Nissin Ion Equipment Co., Ltd., Koka-city (JP)

(72) Inventors: Yuta IWANAMI, Koka-city (JP); Yuya HIRAI, Koka-city (JP); Surguru ITOI, Koka-city (JP)

(73) Assignee: Nissin Ion Equipment Co., Ltd., Koka-city (JP)

(21) Appl. No.: 18/353,301

(22) Filed: Jul. 17, 2023

(30) Foreign Application Priority Data
Jul. 19, 2022 (JP) 2022-114899

(51) Int. Cl. H01J 37/32

(52) U.S. Cl. CPC H01J 37/32449; H01J 37/32522

(57) ABSTRACT

An ion beam irradiation apparatus includes a plasma generation container in which plasma is generated, a vaporizer connected to the plasma generation container, a halogen gas supply passage through which a halogen gas is supplied to the vaporizer, an air supply passage through which air is supplied to the vaporizer, and an evacuation passage through which a reaction product produced through a reaction between the halogen gas and the air is evacuated to an outside of the ion beam irradiation apparatus.

### CROSS-REFERENCE TO RELATED APPLICATION

This Application is based on and claims priority to Japanese Application No. 2022-114899, filed on Jul. 19, 2022, in the Japan Patent Office, the contents of which being incorporated by reference herein in its entirety.

### BACKGROUND

The disclosure relates to an ion beam irradiation apparatus for irradiating a to-be-irradiated object with an ion beam, and a method for use in the ion beam irradiation apparatus.

An ion beam irradiation apparatus generates an ion beam from an ion source, where the ion beam is used for making various semiconductor products. Periodically maintenance of the ion beam irradiation apparatus, and specifically, the ion source, is required.

### SUMMARY

It is an aspect to provide an ion beam irradiation apparatus and method that allows for quickly starting maintenance of an ion source after an operation of the ion source is stopped.

According to an aspect of one or more embodiments, there is provided an ion beam irradiation apparatus comprising a plasma generation container in which plasma is generated; a vaporizer connected to the plasma generation container; a halogen gas supply passage through which a halogen gas is supplied to the vaporizer; an air supply passage through which air is supplied to the vaporizer; and an evacuation passage through which a reaction product produced through a reaction between the halogen gas and the air is evacuated to an outside of the ion beam irradiation apparatus.

According to another aspect of one or more embodiments, there is provided a method for an ion beam irradiation apparatus comprising a plasma generation container in which plasma is generated, a vaporizer connected to the plasma generation container, a halogen gas supply passage through which a halogen gas is supplied into the vaporizer, an air supply passage through which air is supplied to inside of the vaporizer, and an evacuation passage through which a reaction product produced through a reaction between the halogen gas and the air is evacuated to an outside of the ion beam irradiation apparatus, the method comprising after stopping an ion beam producing operation of the ion beam irradiation apparatus: performing one or more times both an air supply step of supplying the air via the air supply passage and an evacuation step of evacuating the reaction product via the evacuation passage; and performing the air supply step again to bring an inside of the ion beam irradiation apparatus to an atmospheric pressure.

According to yet another aspect of one or more embodiments, there is provided a method comprising stopping the supply of a halogen gas to a vaporizer in vacuum chamber of an ion beam irradiation apparatus; performing an air supply step in which air is supplied to the vacuum chamber; performing an evacuation step in which a reaction product between the air and residual halogen gas is evacuated from the vacuum chamber; and performing the air supply step again in which air is supplied to the vacuum chamber to bring the vacuum chamber from a vacuum to an atmospheric pressure.

### BRIEF DESCRIPTION OF THE DRAWINGS

The above and/or other aspects will become apparent and more readily appreciated from the following description of various embodiments, taken in conjunction with the accompanying drawings, in which:

FIG. 1 is a schematic sectional view showing an ion beam irradiation apparatus in a state during an operation of an ion source, according to some embodiments;

FIG. 2 is a schematic plan view of the ion beam irradiation apparatus in FIG. 1 when viewed orthogonally to an X-Y plane;

FIG. 3 is an explanatory diagram for air supply, according to some embodiments;

FIG. 4 is an explanatory diagram for evacuation, according to some embodiments;

FIG. 5 is an explanatory diagram for nitrogen supply, according to some embodiments;

FIGS. 6A and 6B are flowcharts flowchart showing examples of a method, according to some embodiments;

FIG. 7 is a flowchart showing another example of the method, according to some embodiments;

FIG. 8 is a flowchart showing yet another example of the method, according to some embodiments;

FIG. 9 is a flowchart showing still another example of the method, according to some embodiments; and

FIG. 10 is a flowchart showing yet still another example of the method, according to some embodiments.

### DETAILED DESCRIPTION

In maintenance of an ion source used in an ion beam irradiation apparatus, the inside of the ion beam irradiation apparatus in a vacuum atmosphere is changed to an atmospheric atmosphere, whereafter the ion source is demounted from the ion beam irradiation apparatus, and replacement of consumables constituting the ion source are performed.

In the related art, when changing the inside of the ion beam irradiation apparatus from a vacuum atmosphere to atmospheric atmosphere, the inside of the apparatus is filled with a noble gas represented by nitrogen, thereby bringing a pressure inside the apparatus to atmospheric pressure.

There are various types of ion beams, and an ion beam may contain metal ions. In this case, an ion beam containing metal ions can be extracted from plasma generated from vapor of a metal material vaporized using a vaporizer.

With recent progress in research on vaporizers, a vaporizer may be configured such that a metal material such as aluminum or tungsten is placed in a crucible of the vaporizer, and a halogen gas such as chlorine or fluorine is introduced into the crucible to produce a reaction product through a chemical reaction between the metal material and the halogen gas, whereafter the reaction product is heated, and the resulting vapor of the reaction product is supplied to a plasma generation container.

An ion source equipped with the above vaporizer requires that the concentration of a toxic halogen gas remaining in the ion source should be reduced to a sufficiently low level before maintenance. Air is typically not used to purge the toxic halogen gas because air has several disadvantages, for example, causing deterioration of the performance of the ion source by causing oxidation, condensation, and unexpected reactions. Therefore, an inert gas such as dry nitrogen may be used to avoid these disadvantages. In a case where nitrogen gas is supplied to bring the pressure of an ion source to atmospheric pressure, as with the related art, the inside of the ion source is bought to atmospheric pressure by: alternately repeating a step of filling the inside of the ion source with nitrogen gas and a step of evacuating the inside of the ion source, until the concentration of a halogen gas remaining in the ion source is reduced to a sufficiently low level; and then supplying nitrogen gas into the ion source again. In this technique, there are several disadvantages in that it takes a long time until the halogen gas concentration reaches the sufficiently low level, and thus it takes a long time to bring the inside of the ion source to atmospheric pressure and start maintenance.

Therefore, it is an aspect to provide an ion beam irradiation apparatus and gas evacuation method capable of making it possible to more quickly start maintenance of an ion source.

According to some embodiments, there is provided an ion beam irradiation apparatus which comprises: a plasma generation container for generating plasma thereinside; a vaporizer connected to the plasma generation container; a halogen gas supply passage for supplying a halogen gas to the vaporizer; an air supply passage for supplying air to the vaporizer; and an evacuation passage for evacuating a reaction product produced through a reaction between the halogen gas and the air, to outside of the apparatus.

In some embodiments, air is supplied, instead of supplying nitrogen gas as in the related art. Thus, a water component in the supplied air reacts with the halogen gas remaining in the vaporizer, thereby making it possible to quickly reduce the concentration of the halogen gas to a low level, and thus making it possible to quickly start maintenance of the ion source.

In order to reliably prevent oxidation of components, in some embodiments, the ion beam irradiation apparatus may comprise a measuring device for measuring a temperature of the plasma generation container.

In order to make it possible to more quickly start the maintenance of the ion source, in some embodiments, the ion beam irradiation apparatus may comprise a nitrogen supply passage for supplying nitrogen to the plasma generation container.

In order to make it possible to more quickly start the maintenance of the ion source, in some embodiments, the ion beam irradiation apparatus may comprise a cooling passage for cooling the plasma generation container.

According to some embodiments, there is provided a gas evacuation method for use in an ion beam irradiation apparatus comprising: a plasma generation container for generating plasma thereinside; a vaporizer connected to the plasma generation container; a halogen gas supply passage for supplying a halogen gas into the vaporizer; an air supply passage for supplying air to inside of the vaporizer; and an evacuation passage for evacuating a reaction product produced through a reaction between the halogen gas and the air, to outside of the apparatus, the gas evacuation method comprising, before maintenance of the ion beam irradiation apparatus: performing an air supply step of supplying the air via the air supply passage and an evacuation step of evacuating the reaction product via the evacuation passage, one or more times; and then lastly performing the air supply step again to bring inside of the apparatus to atmospheric pressure.

In various embodiments, air is supplied, instead of supplying nitrogen gas as in the related art. Thus, a water component in the supplied air reacts with the halogen gas remaining in the vaporizer, thereby making it possible to early reduce the concentration of the halogen gas to a low level, and thus making it possible to more quickly start maintenance of the ion source.

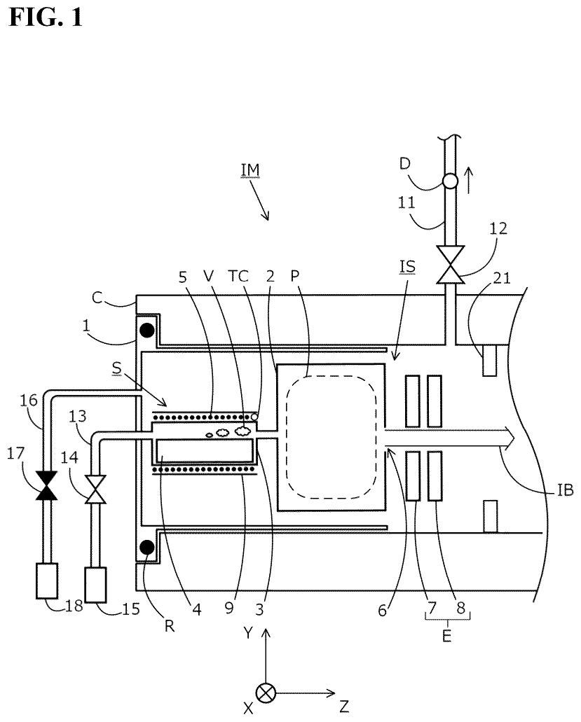

FIG. 1 is a schematic sectional view showing an ion beam irradiation apparatus IM in a state during the operation of an ion source IS, according to some embodiments. For example, the ion beam irradiation apparatus IM is an apparatus configured to irradiate a to-be-irradiated object with an ion beam to introduce impurities into the to-be-irradiated object, or an apparatus configured to irradiate a to-be-irradiated object with an ion beam to modify or cut the surface of the to-be-irradiated object by ions contained in the ion beam. More specifically, an ion implantation apparatus and an ion beam etching apparatus fall under the category of the ion beam irradiation apparatus.

According to various embodiments, the ion source IS may comprise a plasma generation container 2 for generating plasma P thereinside, a vaporizer S having one end connected to the plasma generation container 2, a halogen gas supply passage 13 for supplying a halogen gas to the vaporizer S from the side of the other end of the vaporizer S, and an extraction electrode E for extracting an ion beam IB from the plasma P inside the plasma generation container 2.

In some embodiments, various other components, such as a cathode for generating the plasma P inside the plasma generation container 2, a filament for heating the cathode, a reflective electrode disposed inside the plasma generation container 2 and opposed to the cathode to reflect electrons released from the cathode, toward the cathode, and an electromagnet generating a magnetic field along a direction along which the cathode and the reflective electrode are opposed to each other, inside the plasma generation container 2, may be arranged around the plasma generation container 2. However, illustration of these components is omitted for ease of explanation and conciseness.

A block comprising the plasma generation container 2 and the vaporizer S of the ion source IS is formed as an ion source head and supported by an ion source flange 1 through a non-illustrated structural member. Further, the ion source flange 1 is fixed to a vacuum container C by a non-illustrated fastener such as bolts. The ion source flange 1 is provided with a cooling passage R for cooling the ion source head. The cooling passage R is a circulation passage for a refrigerant or air.

The extraction electrode E may include a suppression electrode 7 for preventing flow of electrons into the plasma generation container 2, and a ground electrode 8 for clamping a ground potential. A non-illustrated DC power supply is connected between the plasma generation container 2 and the suppression electrode 7, while the positive terminal of the DC power supply is connected to the plasma generation container 2. Thus, based on a potential difference between the plasma generation container 2 and the suppression electrode 7, an ion beam IB having a positive electrical charge is extracted from the plasma P through an ion extraction port 6 of the plasma generation container 2.

A first on-off valve 21 is provided on one side of the extraction electrode E oriented in a Z-direction which is an ion beam extraction direction along which the ion beam IB is extracted. The first on-off value 21 is an openable-closable valve element configured to selectively divide a space of the vacuum container C into two spaces located forwardly and backwardly with respect to the first on-off value 21 in the Z-direction, wherein the first on-off value 21 is opened (in an open state) during the operation of the ion source IS.

The vaporizer S is connected to the plasma generation container 2. In some embodiments, the vaporizer S may include a crucible 3 in which a metal material 4 is placed, for example, in the form of a pellet, a powder or a lump, a heater 5 for raising the temperature of the crucible 3, a shield 9 shielding heat release from the heater 5, and a temperature measuring device TC (e.g., a thermocouple) for measuring the temperature of the crucible 3. The vaporizer S further comprises a halogen gas supply passage 13 for supplying a halogen gas such as chlorine or fluorine to the crucible 3.

A halogen gas bottle 15 is attached to the halogen gas supply passage 13 through a second on-off valve 14. During the operation of the ion source IS, the second on-off valve 14 is in an open state. Thus, the halogen gas is supplied from the halogen gas bottle 15 to the crucible 3, and chemically reacts with the metal material 4. When the crucible 3 is heated by the heater 5 to a high temperature, a reaction product produced through a reaction between the halogen gas and the metal material 4 is vaporized, and the resulting vapor V is supplied from the crucible 3 to the plasma generation container 2. The vapor V becomes plasma P in the plasma generation container 2, and the plasma P is extracted as an ion beam IB.

An air supply passage 16 is connected to the ion source flange 1. Air is fed from an air supply source 18 to the air supply passage 16 through a third on-off valve 17. In some embodiments, the air supply source 18 may be an air-filled bottle. In some embodiments, the air supply source 18 may be an air supply line equipped in a factory in which the ion beam irradiation apparatus IM is installed. During the operation of the ion source IS (i.e., during extraction of the ion beam IB from the plasma P inside the plasma generation container 2), the third on-off valve 17 is closed (in a closed state).

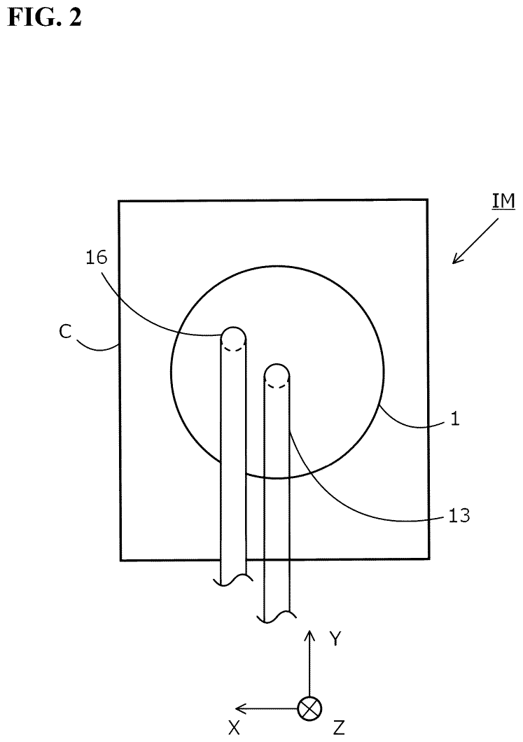

FIG. 2 is a schematic plan view of the ion beam irradiation apparatus IM in FIG. 1 when viewed orthogonally to an X-Y plane. One end of the ion source flange 1 is mounted to the vacuum container C. The air supply passage 16 is connected to the ion source flange 1, and the halogen gas supply passage 13 is mounted to the crucible 3 in FIG. 1 through the ion source flange 1. In order to allow the inside of the vacuum container C to be hermetically sealed, in some embodiments, a non-illustrated vacuum sealing member such as 0-ring may be provided between the ion source flange 1 and the vacuum container C.

The vaporizer S may be prepared to have a flange for mounting the vaporizer S to the ion source flange 1 therethrough, and configured such that the crucible 3 is supported by the flange, and the halogen gas supply passage 13 is connected to the flange.

In order to allow the inside of the vacuum container C to be maintained at a certain degree of vacuum during the operation of the ion source IS, the inside of the vacuum container C is evacuated. Returning to FIG. 1, the evacuation is performed through an evacuation passage 11 connected to the vacuum container C. A fourth on-off valve 12 is interposed in the evacuation passage 11. During the operation of the ion source IS, the fourth on-off valve 12 is in an open state. The evacuation passage 11 is also provided with a concentration measuring device D for measuring a halogen gas concentration.

In some embodiments, the evacuation passage 11 may be connected to a non-illustrated vacuum pump. In some embodiments, the evacuation passage 11 may be connected to an evacuation line equipped in a factory in which the ion beam irradiation apparatus IM is installed.

Before performing maintenance of the ion source IS, the operation of the ion source IS is stopped, and air is supplied into the apparatus.

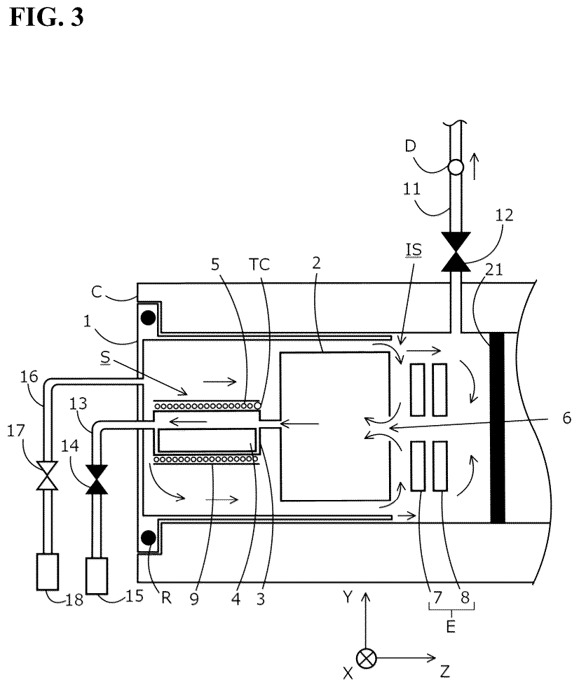

FIG. 3 is an explanatory diagram for air supply, according to some embodiments.

Before starting the supply of air to the vacuum container C, each of the first on-off valve 21, the second on-off valve 14 and the fourth on-off valve 12 is changed to a closed state, and only the third on-off valve 17 is changed to an open state.

Then, air is supplied from the air supply source 18 through the air supply line 16 to respective parts of the ion source IS according to the flow indicated by the arrows in FIG. 3, and is lastly supplied to the inside of the crucible 3 of the vaporizer S.

When the operation of the ion source IS is stopped, the halogen gas supplied to the vaporizer S, the plasma generation container 2, etc., remains inside the apparatus. Thus, when supplying air to the respective parts, the residual halogen gas and a water component of the air react with each other to produce a reaction product (gas).

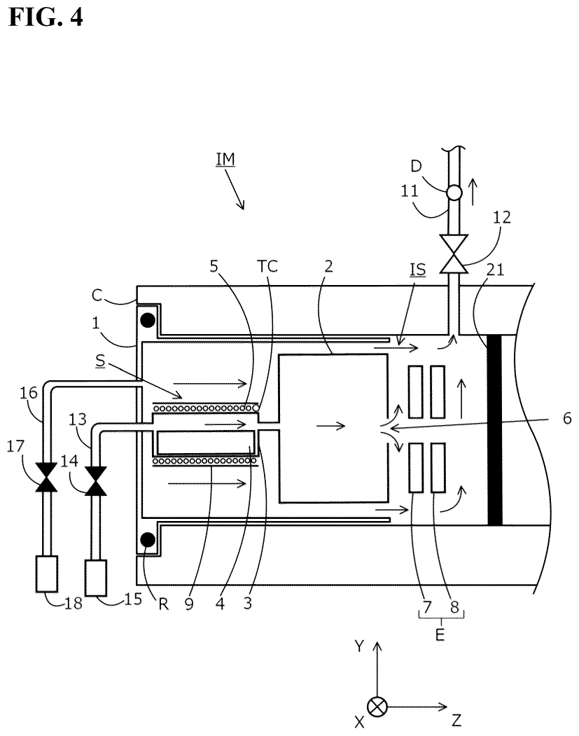

After the elapse of a given time after the air supply is started, or after the pressure of the vacuum container C reaches a given value after the air supply is started, gas inside the vacuum container C is evacuated to the outside of the apparatus. A state at the time of evacuation is depicted in FIG. 4. The term “the outside of the apparatus” here means the outside of the ion beam irradiation apparatus IM, more specifically, the outside of the vacuum container C.

While not illustrated in the figures, in some embodiments, a controller or hardware control logic may be communicatively connected to each of the first on-off valve 21, the second on-off valve 14, the third on-off valve 17, and the fourth on-off valve 12, and the controller may be coded to or the hardware control logic may be configured to control respective open and closed states of each of the first on-off valve 21, the second on-off valve 14, the third on-off valve 17, and the fourth on-off valve 12 as described with respect to FIGS. 3-10.

FIG. 4 is an explanatory diagram for evacuation, according to some embodiments. The first to fourth on-off valves in FIG. 4 are set such that each of the first on-off valve 21, the second on-off valve 14 and the third on-off valve 17 is in the closed state, and the fourth on-off valve 12 is in the open state. In this state, gas in the vacuum container C is evacuated via the evacuation passage 11. The arrowed lines depicted in the vacuum container C represent the flow of gas to be evacuated. In the evacuation process, a halogen gas concentration in the gas being evacuated via the evacuation passage 11 is measured by the concentration measuring device D.

When nitrogen gas is supplied to bring the pressure of the ion source IS to atmospheric pressure as in related art, it takes a long time until the halogen gas concentration reaches a low level. In contrast, in various embodiments, when air is supplied instead of nitrogen, a water component in the supplied air reacts with the residual halogen gas, so that it becomes possible to more quickly reduce the concentration of the halogen gas in the apparatus to a low level.

Then, after the halogen gas concentration reaches the given concentration or less, air is lastly supplied again, as described in connection with FIG. 3, so as to bring the inside of the vacuum container C to atmospheric pressure. This configuration and operation makes it possible to more quickly bring the halogen gas concentration to a low level, and thus to start maintenance of the ion source IS more quickly, as compared to the related art configuration.

In some embodiments, in a situation where the amount of residual halogen gas is relatively large, and therefore the halogen gas concentration cannot be sufficiently reduced within one duration of air supply, the step of performing air supply (air supply step) described in connection with FIG. 3 and the step of evacuating the reaction product (evacuation step) described in connection with FIG. 4 may be repeated a plurality of times, prior to the step of bringing the inside of the vacuum container C to atmospheric pressure in order to demount the ion source IS.

When performing the air supply, there may be a concern that oxygen contained in air oxidizes components constituting the ion source IS. During the operation of the ion source 1S, the plasma generation container 2 has a relatively high temperature, as compared to other components constituting the ion source IS. Metal components (made of a high-melting-point metal, such as tungsten or molybdenum), such as the cathode and the reflective electrode, mounted around the plasma generation container 2, have an accelerated reaction with oxygen under high temperatures. If the metal components are oxidized, the oxidized metal components will hinder the operation of the ion source IS. Thus, it is advantageous to start the air supply after the elapse of a given time once the operation of the ion source IS has stopped. The term “given time” here means a period of time derived by an experimental rule. In some embodiments, the “given time” may be a period of time for the temperature of the plasma generation container 2 to decrease to a given temperature or less.

Instead of waiting for the elapse of the given time, in some embodiments, the temperature of the plasma generation container 2 may be actually measured, and the air supply may be started according to the actually measured value (i.e., once the measured value has dropped below a threshold value, where the threshold value may be set experimentally).

With regard to the temperature measurement of the plasma generation container 2, in some embodiments, a thermocouple may be mounted to the plasma generation container 2 to directly measure the temperature of the plasma generation container 2. IN some embodiments, the temperature measurement may be performed using a radiation thermometer or a thermography, instead of the thermocouple.

In some embodiments, the temperature of the vaporizer S connected to the plasma generation container 2 may be measured by a thermocouple TC, and the temperature of the plasma generation container 2 may be indirectly derived in consideration of a temperature correlation between the vaporizer S and the plasma generation container 2. The temperature correlation may be set experimentally.

In some embodiments, the temperature of the plasma generation container 2 may be reduced by means of natural cooling. However, in view of shortening of cooling time, it is advantageous to perform the cooling using a refrigerant. For example, as depicted in FIGS. 1 to 4, in some embodiments, the plasma generation container 2 supported by the ion source flange 1 can be cooled by forming a cooling passage R in the ion source flange 1 and circulating a refrigerant or air in the cooling passage R.

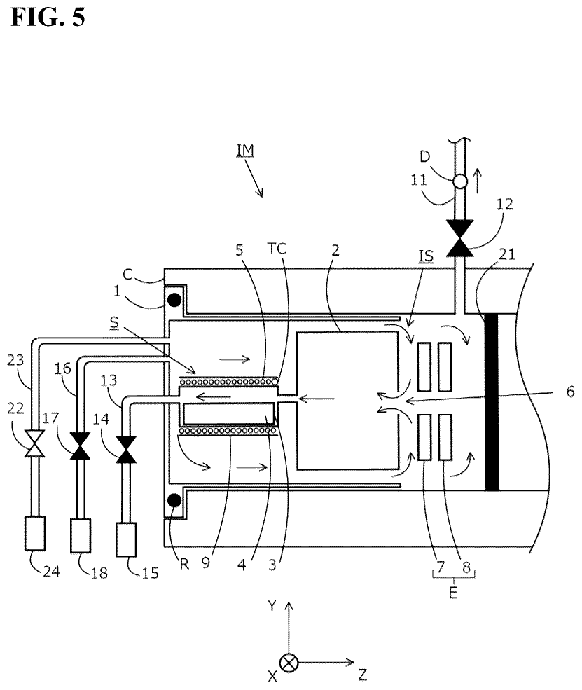

In some embodiments, a configuration as shown in FIG. 5 may be employed to cool the plasma generation container 2.

FIG. 5 is an explanatory diagram for nitrogen supply, according to some embodiments. The embodiment illustrated in FIG. 5 is different from the embodiments illustrated in FIGS. 1-4 in that in the embodiment illustrated in FIG. 5, nitrogen gas is supplied to the inside of the vacuum container C.

One end of a nitrogen supply passage 23 is connected to the ion source flange 1, and the other end of the nitrogen supply passage 23 is connected to a nitrogen supply bottle 24 through a fifth on-off valve 22. Prior to the supply of air to the vacuum container C, the cooling of the plasma generation container 2 is performed by introducing nitrogen via the nitrogen supply passage 23.

That is, a step of supplying nitrogen to cool the plasma generation container 2 (nitrogen supply step) is performed before the start of the air supply step as described with respect to the embodiments of FIGS. 1-4, which makes it possible to further shorten a waiting time before starting the air supply.

In some embodiments, prior to starting the air supply after the nitrogen supply, nitrogen inside the apparatus is evacuated to the outside of the ion beam irradiation apparatus IM via the evacuation passage 11. In some embodiments, the supply and evacuation of nitrogen may be performed a plurality of times to sufficiently reduce the temperature of the plasma generation container 2.

In the embodiment illustrated in FIG. 5, the nitrogen supply passage 23 and the air supply passage 16 are connected to the ion source flange 1, individually. In some embodiments, the nitrogen supply passage 23 and the air supply passage 16 connected to the ion source flange 1 may be partly unified. In this case, the two supply passages may be branched halfway from the unified or common supply passage.

In a situation in which the temperature of the vaporizer S is relatively high at the start of maintenance of the ion source IS, and it takes a long time before the vaporizer S can be demounted, air from the air supply passage 16 and/or nitrogen from the nitrogen supply passage 23 may cool the vaporizer S. In some embodiments, air from the air supply passage 16 or nitrogen from the nitrogen supply passage 23 may cool the vaporizer S.

Thus, in some embodiments, in addition to the air supply passage 16 and the nitrogen supply passage 23 illustrated in FIG. 5, a gas supply passage for cooling the vaporizer S may be provided.

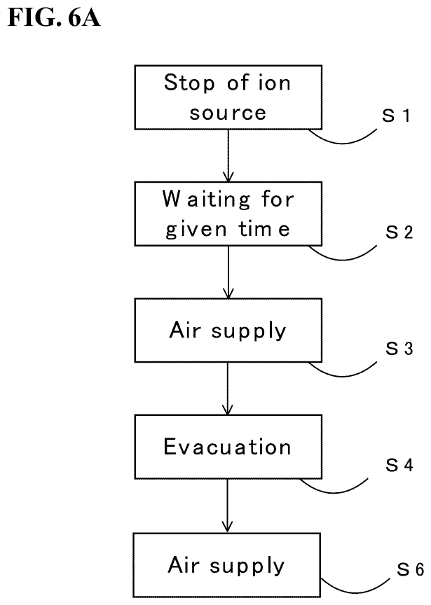

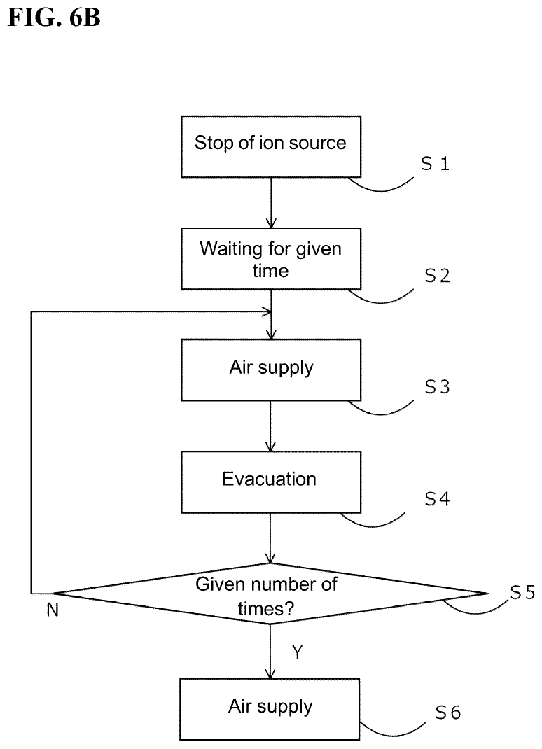

With reference to FIGS. 6A to 10, the aforementioned method will be described in detail.

FIGS. 6A and 6B are flowcharts showing examples of a method, according to some embodiments. As illustrated in FIG. 6A, in step 51, the operation of the ion source IS is stopped. For example, in some embodiments, application of a voltage to the extraction electrode E, application of a voltage to the plasma generation container 2, energization to the heater 5 of the vaporizer S, and a supply of the halogen gas to the vaporizer S may be stopped. In some embodiments, the circulation of a refrigerant or air in the cooling passage R of the ion source flange 1 may be continued.

In conjunction with stopping the operation of the ion source IS, each of the first on-off valve 21, the second on-off valve 14 and the fourth on-off valve 12 is changed to the closed state.

Subsequently, in step S2, the method may wait for a given time. For example, in some embodiments, the method may wait until an elapsed time from the stopping of the ion source IS has occurred. As another example, an elapsed time since the operation of the ion source IS was stopped is counted, and the next step not performed until a given time (e.g., several ten minutes) has elapsed. For another example, the temperature of the plasma generation container 2 may be measured, and the method may wait until the temperature of the plasma generation container 2 is reduced to a given temperature or less.

Then, after the given time has elapsed, in step S3, air is supplied. For example, air is supplied to the vacuum chamber C as described above. More specifically, the third on-off valve 17 may be changed to the open state to perform the air supply.

Thereafter, in step S4, evacuation is performed. For example, after the elapse of a given time after the air supply was started, or after the pressure of the inside of the apparatus reaches a given pressure after the air supply was started, the inside of the apparatus may be evacuated.

According to the evacuation, gas which is a reaction product produced through a reaction between water in air and the halogen gas remaining in the ion beam irradiation apparatus is evacuated to the outside of the ion beam irradiation apparatus.

In step S6, air is supplied. For example, air is supplied again after the evacuation is performed in order to bring the inside of the ion beam irradiation apparatus IM (and thus the ion source IS) to an atmospheric pressure. Once the ion beam irradiation apparatus IM is at the atmospheric pressure, maintenance of the ion source IS may be performed.

FIG. 6A illustrates an example in which the evacuation step is performed once. However, depending on the volume of the ion beam irradiation apparatus IM, there is a possibility that it is difficult to reduce the concentration of the halogen gas remaining in the ion beam irradiation apparatus to a given level within one duration of evacuation. In this case, the air supply in the step S3 and the evacuation in the step S4 may be repeatedly performed, as illustrated in FIG. 6B.

FIG. 6B illustrates an example in which the air supply and evacuation steps are performed multiple times. In FIG. 6B, steps S1 to S4 and S6 are substantially the same as in FIG. 6A, and therefore repeated description thereof is omitted for conciseness. After the evaluation step S4, in step S5, it is determined whether the air supply in the step S3 and the evacuation in the step S4 are performed a number of times. For example, in some embodiments, the number of times of the repetition may be preliminarily set at the first execution of step S5. However, this is only an example and, in some embodiments, other timings for setting the number of times of repetition may be used. For example, in some embodiments, the number of repetition times may be set at the beginning of the method, or may be stored in a memory accessible by the controller or the hardware logic.

After it is determined in the step S5 that the air supply in the step S3 and the evacuation in the step S4 are performed the given number of times (i.e., step S5, Y), the air supply for bringing the inside of the ion beam irradiation apparatus to atmospheric pressure is lastly performed in step S6. When it is determined in the step S5 that the air supply in the step S3 and the evacuation in the step S4 have not been performed the given number of times (i.e., step S5, N), the method may return to step S3.

The use of the above gas evacuation method makes it possible to more quickly reduce the concentration of the residual halogen gas to a low level, and thus makes it possible to may quickly start maintenance of the ion source IS.

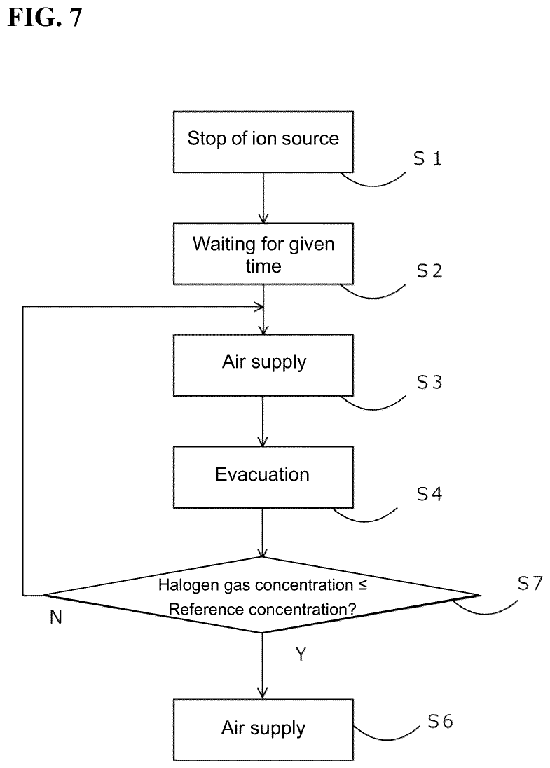

In the example in FIG. 6B, the number of times the air supply in the step S3 and the evacuation in the step S4 were performed is determined in the step S5. In some embodiments, the number of times the air supply and the evacuation were performed may be determined by actually measuring the concentration of the halogen gas being evacuated via the evacuation passage 11, and determining whether the measured concentration reaches a reference concentration. Accordingly, in another example of the method in FIG. 7, in place of the step S5 in FIG. 5, a step S7 of comparing the measured halogen gas concentration with a reference concentration is added.

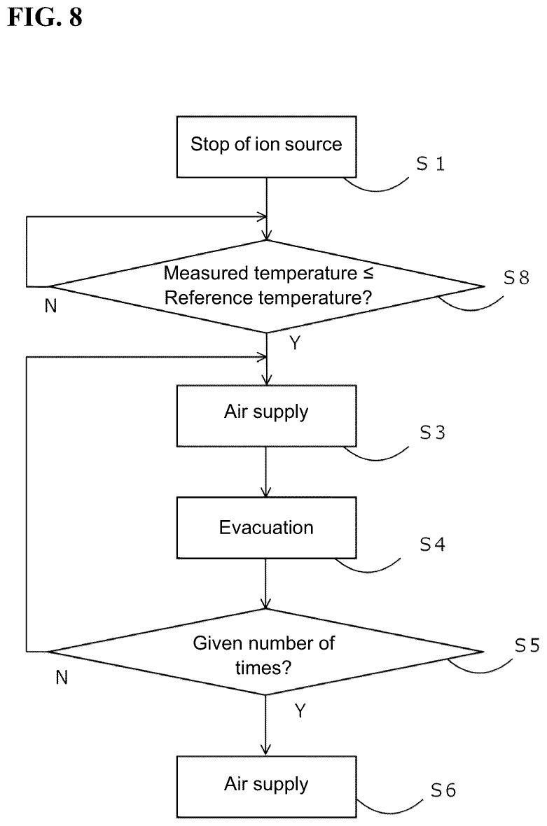

In the examples in FIG. 6A and 6B, the step S2 is configured such that after stop of the operation of the ion source, the method waits for a given time has elapsed or until the temperature of the plasma generation container 2 is reduced to a low level. In some embodiments, as illustrated in FIG. 8, the step S2 may be replaced with a step S8 of actually measuring the temperature of the plasma generation container 2, and comparing the measured temperature with a reference temperature. If the measured temperature is less than or equal to the reference temperature (S8, Y), the method proceeds to step S3. If the measured temperature is greater than the reference temperature (S8, N), the method returns to step S8 and the temperature is measured again. In this way, time passes until the temperature has fallen to a level corresponding to the reference temperature.

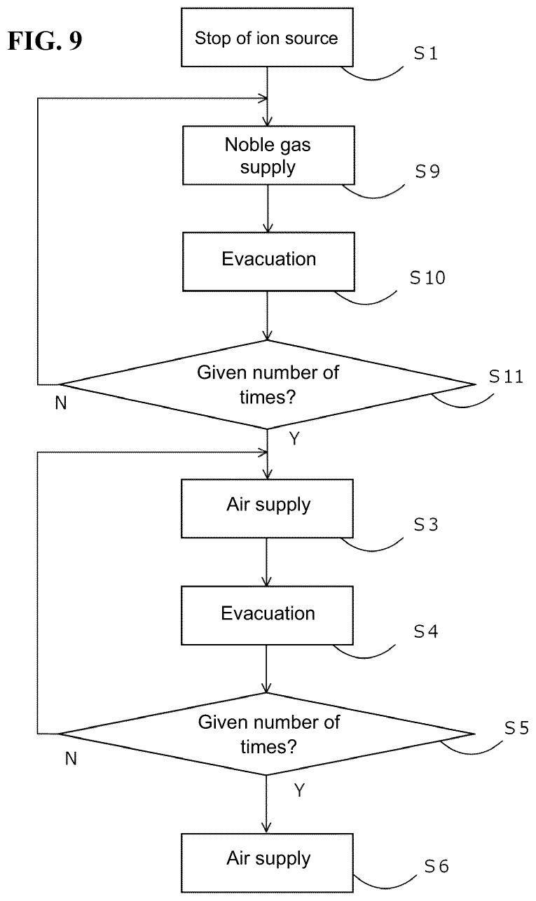

In order to effectively reduce the temperature of the plasma generation container 2, it is possible to employ a configuration in which a noble gas is supplied after stop of the operation of the ion source IS. Specifically, as shown in FIG. 9, in a period after stop of the operation of the ion source IS in the step S1 until the air supply is performed in the step S3, a step S9 of supplying a noble gas such as nitrogen gas or argon gas into the plasma generation container 2, a step S10 of, after the noble gas supply, evacuating the noble gas from the ion beam irradiation apparatus, and a step S11 of determining whether the steps S9 and S10 are performed a predetermined given number of times, may be performed. In other words, steps S9 to S11 may be inserted between steps S1 and S3 (in place of step S2 in FIG. 6B). It is noted that the noble gas may also be introduced in the method of FIG. 6A (that is, steps S9 to S11 may be inserted between steps S1 and S3 (in the place of step S2 in FIG. 6A)).

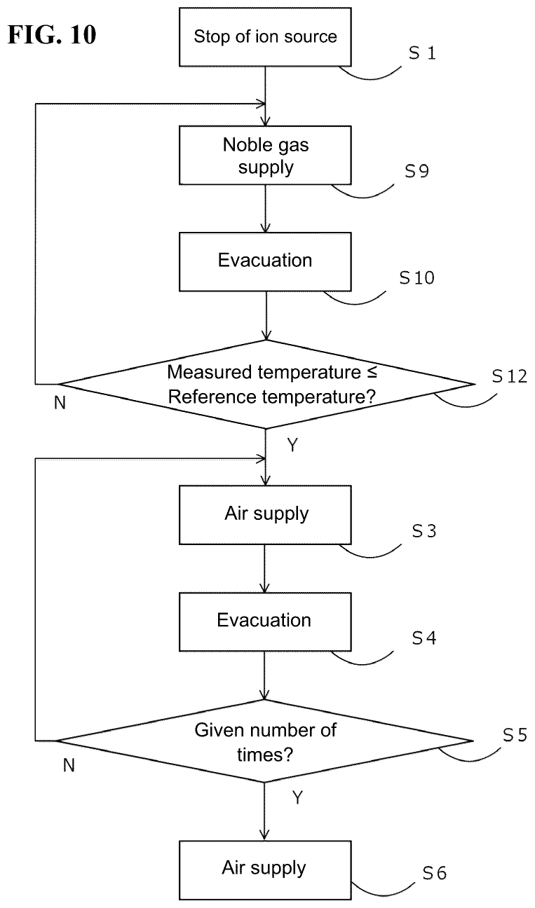

In some embodiments, as illustrated in FIG. 10, in place of the step S11 illustrated in FIG. 9, a step S12 may be provided. In step S12, after the noble gas supply and the evacuation of the inside of the apparatus, measuring the temperature of the plasma generation container 2 directly or indirectly, and comparing the measured temperature with a reference temperature may be performed.

Although the step of air supply S3 and the subsequent steps S4-S6 in the examples in FIGS. 8 to 10 are the same as those in the example in FIG. 6B, these steps may be replaced by those in the example in FIG. 7. Additionally, the step of the air supply S3 and the subsequent steps S4-S6 in FIGS. 8 to 10 may also be replaced with steps S3, S4 and S6 illustrated in FIGS. 6A.

The embodiments illustrated in FIGS. 1 to 5 have been described based on an example in which the evacuation passage 11 is also used to evacuate the inside of the ion beam irradiation apparatus during the operation of the ion source IS. However, the evacuation passage 11 for evacuating a reaction product produced through a reaction between air and a halogen gas does not necessarily need to have such a function. For example, an additional evacuation passage may be provided, and the inside of the ion beam irradiation apparatus may be evacuated during the operation of the ion source IS using the additional evacuation passage.

It is to be understood that various embodiments have been described herein, but various changes and modifications may be made therein without departing from the spirit and scope thereof as set forth in appended claims.

What is claimed is:

1. An ion beam irradiation apparatus comprising:
a plasma generation container in which plasma is generated;
a vaporizer connected to the plasma generation container;
a halogen gas supply passage through which a halogen gas is supplied to the vaporizer;
an air supply passage through which air is supplied to the vaporizer; and
an evacuation passage through which a reaction product produced through a reaction between the halogen gas and the air is evacuated to an outside of the ion beam irradiation apparatus.

2. The ion beam irradiation apparatus as recited in claim 1, comprising a measuring device that measures a temperature of the plasma generation container.

3. The ion beam irradiation apparatus as recited in claim 1, comprising a nitrogen supply passage through which nitrogen is supplied to the plasma generation container.

4. The ion beam irradiation apparatus as recited in claim 1, comprising a cooling passage through which a coolant is provided for cooling the plasma generation container.

5. The ion beam irradiation apparatus as recited in claim 1, further comprising:
a vacuum chamber comprising the plasma generation container and the vaporizer;
a halogen supply valve in the halogen gas supply passage;
an air supply valve in the air supply passage; and
an evacuation valve in the evacuation passage,
wherein the halogen gas supply passage is communicatively connected to the vaporizer, the air supply passage is communicatively connected to the vacuum chamber, and the evacuation passage is communicatively connected to the vacuum chamber, and
wherein the halogen supply value controls a supply of the halogen gas to the vaporizer, the air supply valve controls a supply of the air to the vacuum chamber, and the evacuation valve controls an evacuation of the reaction product from the vacuum chamber.

6. The ion beam irradiation apparatus as recited in claim 5, further comprising a halogen gas supply line connected to the halogen gas supply passage and an air supply line connected to the air supply passage.

7. The ion beam irradiation apparatus as recited in claim 5, further comprising a halogen gas supply bottle connected to the halogen gas supply passage and an air supply bottle connected to the air supply passage.

8. A method for an ion beam irradiation apparatus comprising a plasma generation container in which plasma is generated, a vaporizer connected to the plasma generation container, a halogen gas supply passage through which a halogen gas is supplied into the vaporizer, an air supply passage through which air is supplied to inside of the vaporizer, and an evacuation passage through which a reaction product produced through a reaction between the halogen gas and the air is evacuated to an outside of the ion beam irradiation apparatus, the method comprising:
after stopping an ion beam producing operation of the ion beam irradiation apparatus:
performing one or more times both an air supply step of supplying the air via the air supply passage and an evacuation step of evacuating the reaction product via the evacuation passage; and
performing the air supply step again to bring an inside of the ion beam irradiation apparatus to an atmospheric pressure.

9. The method as recited in claim 8, wherein the ion beam irradiation apparatus further comprises a vacuum chamber including the plasma generation container and the vaporizer, and
wherein the air supply step supplies the air to the vacuum chamber and the evacuation step evacuates the reaction product from the vacuum chamber, and
wherein the air supply step is performed again to bring the inside of the vacuum chamber from a vacuum to the atmospheric pressure.

10. A method comprising:
stopping a supply of halogen gas to a vaporizer in a vacuum chamber of an ion beam irradiation apparatus;
performing an air supply step in which air is supplied to the vacuum chamber;
performing an evacuation step in which a reaction product between the air and residual halogen gas is evacuated from the vacuum chamber; and
performing the air supply step again in which air is supplied to the vacuum chamber to bring the vacuum chamber from a vacuum to an atmospheric pressure.

11. The method as recited in claim 10, wherein before performing the air supply step again, both the air supply step and the evacuation step are performed a plurality of times.

12. The method as recited in claim 10, further comprising waiting for a period of time between the air supply step and the evacuation step.

13. The method as recited in claim 10, further comprising waiting for a period of time between stopping the supply of halogen gas and performing the air supply step.

14. The method as recited in claim 10, further comprising, after stopping the supply of halogen gas, measuring a temperature of a plasma generation container of the ion beam irradiation apparatus, and waiting until the temperature of the plasma generation container is less than a threshold temperature before performing the air supply step.

15. The method as recited in claim 10, further comprising cooling a plasma generation container of the ion beam irradiation apparatus with a coolant.

16. The method as recited in claim 10, further comprising supplying nitrogen to a plasma generation container of the ion beam irradiation apparatus.
